(19) United States
(12) Patent Application Publication
(10) Pub. No.: US 2025/0253681 A1
(43) Pub. Date: Aug. 7, 2025

(54) STORAGE BATTERY CONTROL DEVICE, AND POWER STORAGE SYSTEM

(71) Applicant: YAZAKI CORPORATION, Tokyo (JP)

(72) Inventor: Takahiro Syouda, Susono-shi (JP)

(21) Appl. No.: 19/190,594

(22) Filed: Apr. 26, 2025

Related U.S. Application Data
(63) Continuation of application No. PCT/JP2023/038797, filed on Oct. 26, 2023.

(30) Foreign Application Priority Data
Nov. 30, 2022 (JP) 2022-191255

(51) Int. Cl. H02J 7/00

(52) U.S. Cl. CPC H02J 7/0019; H02J 7/0048; H02J 7/005; H02J 7/0063; H02J 7/007182

(57) ABSTRACT

A storage battery control device executes: a first process of discharging storage battery modules from a predetermined charged state by a predetermined discharge amount and recording a module voltage and a string current; a second process of discharging storage battery modules that are discharged by the predetermined discharge amount to a predetermined discharged state; a third process of charging storage battery modules that are discharged to the predetermined discharged state by a predetermined charge amount; a fourth process of discharging storage battery modules that are charged by the predetermined charge amount to the predetermined discharged state and recording a module voltage and a string current; and a fifth process of generating voltage transition information at the time of discharging storage battery modules based on the module voltage and the string current recorded in the first process and the module voltage and the string current recorded in the fourth process.

### CROSS-REFERENCE TO RELATED APPLICATIONS

This is a continuation of International Application No. PCT/JP2023/038797 filed on Oct. 26, 2023, and claims priority from Japanese Patent Application No. 2022-191255 filed on Nov. 30, 2022, the entire content of which is incorporated herein by reference.

### TECHNICAL FIELD

The present invention relates to a storage battery control device and a power storage system.

### BACKGROUND ART

A state of health (SOH) estimation device that estimates an SOH indicating a degree of health of a battery is known (for example, see Patent Literatures 1 and 2). In the SOH estimation device disclosed in Patent Literature 1, when the charging of a storage battery ends, a voltage of the storage battery is acquired from a voltage detection unit, the measurement of a polarization recovery time is started, and when a difference between the acquired voltage and a voltage acquired again is equal to or larger than a predetermined voltage, the measurement of the polarization recovery time ends. The SOH estimation device estimates the SOH of the storage battery based on the measured polarization recovery time.

The SOH estimation device described in Patent Literature 2 specifies a state of charge (SOC) based on an SOC-OCV curve line indicating a correlation between the SOC and an open circuit voltage (OCV), and estimates an SOH of a storage battery based on the specified SOC.

On the other hand, a power storage system that includes bypass circuits for a plurality of respective storage batteries connected in series is known (see, for example, Patent Literature 3). In the power storage system described in Patent Literature 3, when the storage batteries reach a fully discharged state or a fully charged state, the bypass circuit is controlled by a controller to switch the storage battery from a connection state to a bypass state.

### CITATION LIST

### Patent Literature

Patent Literature 1: JP2013-148452A
Patent Literature 2: JP2021-71320A
Patent Literature 3: JP2022-29299A

### SUMMARY OF INVENTION

### Technical Problem

In the power storage system described in Patent Literature 3, it is assumed that the storage batteries are discharged for the purpose of acquiring an SOC-OCV curve line. In this assumption, when there is a difference in deterioration states of the plurality of storage batteries, while all the storage batteries reach the fully discharged state, the storage battery having a higher deterioration degree reaches the fully discharged state in advance, and the storage battery is switched from the connection state to the bypass state. Accordingly, the SOC-OCV curve line for the storage battery becomes discontinuous at the time of switching the storage battery from the connection state to the bypass state. Therefore, it is necessary to perform discharge for the purpose of acquiring the SOC-OCV curve line for each storage battery, and an interruption time of the operation of the power storage system becomes long.

In view of the above circumstances, an object of the present invention is to provide a power storage system and a storage battery control device capable of efficiently acquiring voltage transition information on storage batteries in the power storage system including a storage battery string in which the storage batteries are switched between a bypass state and a connection state.

### Solution to Problem

A storage battery control device of the present invention is a storage battery control device for controlling a power storage system including a storage battery string including a plurality of storage batteries connected in series and a plurality of bypass circuits provided for the respective storage batteries and configured to switch the storage batteries between a connection state and a bypass state, and a power converter configured to convert input and output power of the storage battery string, and the storage battery control device executes: a first process of discharging the plurality of storage batteries from a predetermined charged state by a predetermined discharge amount and recording a voltage of the storage batteries and a current of the storage battery string; a second process of discharging the plurality of storage batteries that are discharged by the predetermined discharge amount to a predetermined discharged state; a third process of charging the plurality of storage batteries that are discharged to the predetermined discharged state by a predetermined charge amount; a fourth process of discharging the plurality of storage batteries that are charged by the predetermined charge amount to the predetermined discharged state and recording a voltage of the storage batteries and a current of the storage battery string; and a fifth process of generating voltage transition information indicating voltage transitions at the time of discharging the plurality of storage batteries based on the voltage of the storage batteries and the current of the storage battery string recorded in the first process and the voltage of the storage batteries and the current of the storage battery string recorded in the fourth process.

A storage battery control device of the present invention is a storage battery control device for controlling a power storage system including a storage battery string including a plurality of storage batteries connected in series and a plurality of bypass circuits provided for the respective storage batteries and configured to switch the storage batteries between a connection state and a bypass state, and a power converter configured to convert input and output power of the storage battery string, and the storage battery control device executes: a first process of charging the plurality of storage batteries from a predetermined discharged state by a predetermined charge amount and recording a voltage of the storage batteries and a current of the storage battery string; a second process of charging the plurality of storage batteries that are charged by the predetermined charge amount to a predetermined charged state; a third process of discharging the plurality of storage batteries that are charged to the predetermined charged state by a predetermined discharge amount; a fourth process of charging the plurality of storage batteries that are discharged by the predetermined discharge amount to the predetermined charged state and recording a voltage of the storage batteries and a current of the storage battery string; and a fifth process of generating voltage transition information indicating voltage transitions at the time of charging the plurality of storage batteries based on the voltage of the storage batteries and the current of the storage battery string recorded in the first process and the voltage of the storage batteries and the current of the storage battery string recorded in the fourth process.

A power storage system of the present invention is a power storage system including: a storage battery string including a plurality of storage batteries connected in series and a plurality of bypass circuits provided for the respective storage batteries and configured to switch the storage batteries between a connection state and a bypass state; a power converter configured to convert input and output power of the storage battery string; and a storage battery control device configured to control the bypass circuits and the power converter, in which the storage battery control device executes: a first process of discharging the plurality of storage batteries from a predetermined charged state by a predetermined discharge amount and recording a voltage of the storage batteries and a current of the storage battery string; a second process of discharging the plurality of storage batteries that are discharged by the predetermined discharge amount to a predetermined discharged state; a third process of charging the plurality of storage batteries that are discharged to the predetermined discharged state by a predetermined charge amount; a fourth process of discharging the plurality of storage batteries that are charged by the predetermined charge amount to the predetermined discharged state and recording a voltage of the storage batteries and a current of the storage battery string; and a fifth process of generating voltage transition information indicating voltage transitions at the time of discharging the plurality of storage batteries based on the voltage of the storage batteries and the current of the storage battery string recorded in the first process and the voltage of the storage batteries and the current of the storage battery string recorded in the fourth process.

A power storage system of the present invention is a power storage system including: a storage battery string including a plurality of storage batteries connected in series and a plurality of bypass circuits provided for the respective storage batteries and configured to switch the storage batteries between a connection state and a bypass state; a power converter configured to convert input and output power of the storage battery string; and a storage battery control device configured to control the bypass circuits and the power converter, in which the storage battery control device executes: a first process of charging the plurality of storage batteries from a predetermined discharged state by a predetermined charge amount and recording a voltage of the storage batteries and a current of the storage battery string; a second process of charging the plurality of storage batteries that are charged by the predetermined charge amount to a predetermined charged state; a third process of discharging the plurality of storage batteries that are charged to the predetermined charged state by a predetermined discharge amount; a fourth process of charging the plurality of storage batteries that are discharged by the predetermined discharge amount to the predetermined charged state and recording a voltage of the storage batteries and a current of the storage battery string; and a fifth process of generating voltage transition information indicating voltage transitions at the time of charging the plurality of storage batteries based on the voltage of the storage batteries and the current of the storage battery string recorded in the first process and the voltage of the storage batteries and the current of the storage battery string recorded in the fourth process.

### Advantageous Effects of Invention

According to the present invention, the voltage transition information of the storage batteries can be efficiently acquired in the power storage system including the storage battery string in which the storage batteries are switched between the bypass state and the connection state.

### BRIEF DESCRIPTION OF DRAWINGS

FIG. 1 is a circuit diagram schematically illustrating a power storage system including a storage battery control device according to an embodiment of the present invention.

FIG. 2 is a flowchart illustrating a process of a system controller illustrated in FIG. 1 acquiring a discharge capacity-module voltage curve line indicating a correlation between a discharge capacity and a voltage of a storage battery module.

FIG. 3 is a graph illustrating the correlation between the discharge capacity and the voltage of the storage battery module during the execution of the process illustrated in the flowchart of FIG. 2.

FIG. 4 is a graph illustrating the correlation between the discharge capacity and the voltage of the storage battery module during the execution of the process illustrated in the flowchart of FIG. 2.

FIG. 5 is a graph illustrating the discharge capacity-module voltage curve line generated by the process illustrated in the flowchart of FIG. 2.

FIG. 6 is a graph illustrating the discharge capacity-module voltage curve line generated by the process illustrated in the flowchart of FIG. 2.

FIG. 7 is a graph illustrating the discharge capacity-module voltage curve line generated by the process illustrated in the flowchart of FIG. 2.

FIG. 8 is a flowchart illustrating a process of the system controller illustrated in FIG. 1 acquiring a charge capacity-module voltage curve line indicating a correlation between a charge capacity and a voltage of the storage battery module.

FIG. 9 is a graph illustrating the correlation between the charge capacity and the voltage of the storage battery module during the execution of the process illustrated in the flowchart of FIG. 8.

FIG. 10 is a graph illustrating the correlation between the charge capacity and the voltage of the storage battery module during the execution of the process illustrated in the flowchart of FIG. 8.

FIG. 11 is a graph illustrating the charge capacity-module voltage curve line generated by the process illustrated in the flowchart of FIG. 8.

FIG. 12 is a graph illustrating the charge capacity-module voltage curve line generated by the process illustrated in the flowchart of FIG. 8.

FIG. 13 is a graph illustrating the charge capacity-module voltage curve line generated by the process illustrated in the flowchart of FIG. 8.

### DESCRIPTION OF EMBODIMENTS

Hereinafter, the present invention will be described with reference to a preferred embodiment. The present invention is not limited to embodiments to be described below, and the embodiments can be appropriately modified without departing from the scope of the present invention. In the embodiments to be described below, a part of configurations may be not described or shown in the drawings, and regarding details of the omitted techniques, publicly known or well-known techniques will be appropriately applied as long as there is no contradiction with the contents to be described below.

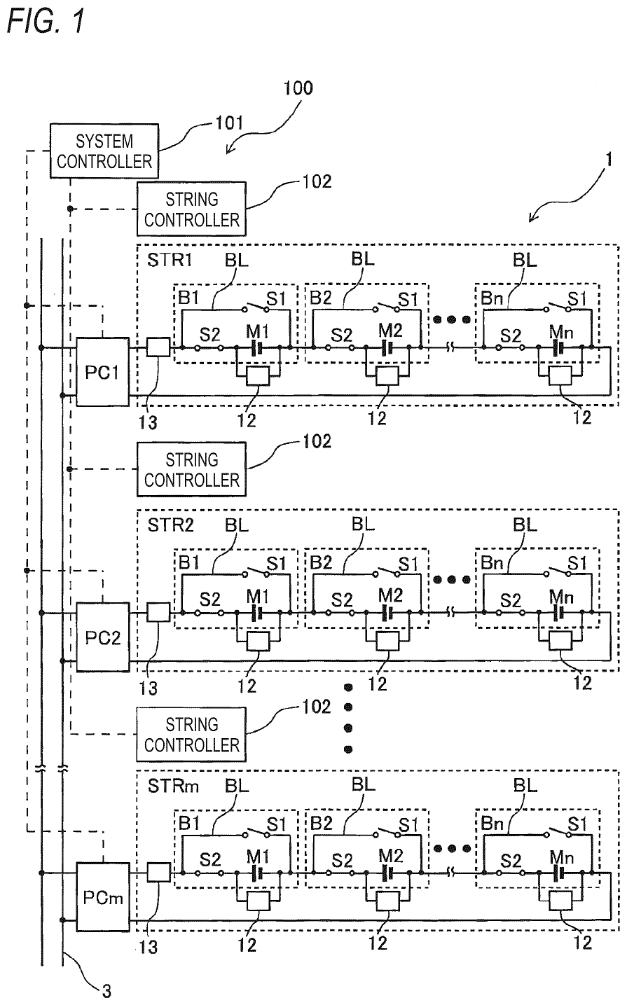

FIG. 1 is a circuit diagram schematically illustrating a power storage system 1 including a storage battery control device 100 according to an embodiment of the present invention. As illustrated in FIG. 1, the power storage system 1 includes m (m is an integer of two or more) sets of storage battery strings STR1 to STRm, a string bus 3, m power converters PC1 to PCm, and the storage battery control device 100. The m sets of storage battery strings STR1 to STRm are connected to each other via the m power converters PC1 to PCm and the string bus 3, and are connected to an external system (not shown). The power storage system 1 is a stationary or in-vehicle power supply.

The storage battery strings STR1 to STRm each include n (n is an integer of 2 or more) storage battery modules M1 to Mn connected in series. Although not particularly limited, the storage battery modules M1 to Mn of the present embodiment are obtained by regenerating used storage batteries, and there is a difference in deterioration states of the storage battery modules M1 to Mn. The storage battery modules M1 to Mn are secondary batteries such as lithium ion batteries and lithium ion capacitors.

The storage battery modules M1 to Mn are charged with power supplied from the external system through the string bus 3 and the power converters PC1 to PCm, and discharge the charged power through the power converters PC1 to PCm and the string bus 3 to supply the power to the external system.

The external system includes a load, a power generator, and the like. When the power storage system 1 is a stationary power supply, home appliances, commercial power supply systems, and the like serve as loads, and a solar photovoltaic power generation system or the like serves as a power generator. On the other hand, when the power storage system 1 is an in-vehicle power supply, a driving motor, an air conditioner, various in-vehicle electrical components, and the like serve as loads. The driving motor serves as both a load and a power generator.

The storage battery strings STR1 to STRm may include n storage battery cells or storage battery packs connected in series instead of the n storage battery modules M1 to Mn connected in series. The power storage system 1 may include a bypass circuit that bypasses each storage battery cell or each storage battery pack.

The power converters PC1 to PCm are DC/DC converters or DC/AC converters, and are connected to the string bus 3. A positive electrode of the storage battery module M1 at a start end and a negative electrode of the storage battery module Mn at a terminal end are connected to each of the power converters PC1 to PCm.

When the storage battery strings STR1 to STRm are charged, the power converters PC1 to PCm convert a voltage input from the string bus 3 and output the converted voltage to a plurality of storage battery modules M1 to Mn. On the other hand, when the storage battery strings STR1 to STRm are discharged, the power converters PC1 to PCm convert the voltage input from the plurality of storage battery modules M1 to Mn and output the converted voltage to the string bus 3. When a current flowing through the string bus 3 is an alternating current, each of the power converters PC1 to PCm is provided with a synchronization unit that follows a change in an instantaneous value.

The storage battery strings STR1 to STRm each include n voltage sensors 12, a current sensor 13, and n bypass circuits B1 to Bn. The voltage sensor 12 is connected between positive and negative electrode terminals of each of the storage battery modules M1 to Mn. The voltage sensor 12 measures an inter-terminal voltage of each of the storage battery modules M1 to Mn.

The current sensor 13 is provided in a current path of the storage battery strings STR1 to STRm. The current sensor 13 measures a charge and discharge current (hereinafter, may be referred to as a string current) of the storage battery strings STR1 to STRn.

The bypass circuits B1 to Bn are set for the respective storage battery modules M1 to Mn. Each of the bypass circuits B1 to Bn includes a bypass line BL and switches S1 and S2. The bypass line BL is a power line that bypasses each of the storage battery modules M1 to Mn.

The switch S1 is provided on the bypass line BL. The switch S1 is, for example, a semiconductor switch, a mechanical switch, or a relay. The switch S2 is provided between a positive electrode of each of the storage battery modules M1 to Mn and one end of the bypass line BL. The switch S2 is, for example, a semiconductor switch, a mechanical switch, or a relay.

The storage battery module M1 at the start end and the storage battery module Mn at the terminal end are connected to the external system via each of the power converters PC1 to PCm and the string bus 3. When the switches S1 are opened and the switches S2 are closed in all the bypass circuits B1 to Bn, all the storage battery modules M1 to Mn are connected in series to the external system. On the other hand, when the switches S2 are opened and the switches S1 are closed in any one of the bypass circuits B1 to Bn, the storage battery modules M1 to Mn corresponding to the bypass circuits B1 to Bn are bypassed.

The storage battery control device 100 includes n string controllers 102 and a system controller 101. The system controller 101 controls the power converters PC1 to PCm. On the other hand, the string controller 102 controls the bypass circuits B1 to Bn and transmits information on states of the bypass circuits B1 to Bn (opening and closing of the switches S1 and S2) to the system controller 101. The string controller 102 receives a detection signal of each voltage sensor 12 and a detection signal of each current sensor 13 and transmits the detection signals to the system controller 101.

The system controller 101 estimates a battery state (hereinafter, referred to as state estimation) such as an SOH or SOC of the storage battery modules M1 to Mn based on an SOC-OCV curve line (discharge capacity-module voltage curve line or charge capacity-module voltage curve line to be described later) stored in advance and the detection signals of the voltage sensor 12 and the current sensor 13. In particular, in the present embodiment, the system controller 101 performs a discharge process or a charge process of the target storage battery strings STR1 to STRm that need to acquire basic data for state estimation such as the SOH or SOC for the purpose of acquiring the SOC-OCV curve line serving as the basic data. The system controller 101 may execute only the discharge process for the purpose of acquiring the discharge capacity-module voltage curve line, or may execute only the charge process for the purpose of acquiring the charge capacity-module voltage curve line. Furthermore, the system controller 101 may execute both the discharge process for the purpose of acquiring the discharge capacity-module voltage curve line, and the charge process for the purpose of acquiring the charge capacity-module voltage curve line.

Here, a predetermined range with respect to the discharge capacities of the storage battery modules M1 to Mn is defined as SOC=100%. The SOC can be acquired by collating the measured or estimated voltage of the storage battery modules M1 to Mn (which corresponds to the OCV and may be hereinafter referred to as a module voltage) with the SOC-OCV curve line.

A current total capacity of the storage battery modules M1 to Mn can be calculated by converting a charge and discharge capacity in the predetermined range of the SOC-OCV curve line into SOC=100%. In addition, the SOH can be calculated by obtaining a ratio of an initial total capacity to the current total capacity of the storage battery modules M1 to Mn or obtaining a ratio of capacities in a predetermined range of an initial SOC-OCV curve line and a current SOC-OCV curve line. By comparing the initial SOC-OCV curve line with the current SOC-OCV curve line, it is also possible to determine failures, mounting defects, and the like of the storage battery modules M1 to Mn.

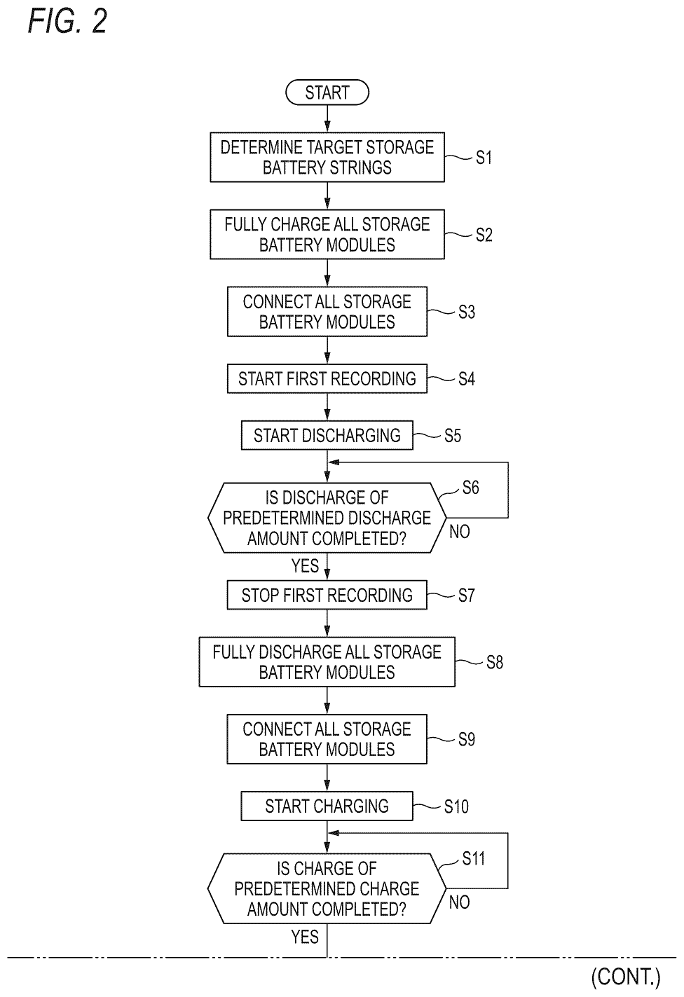

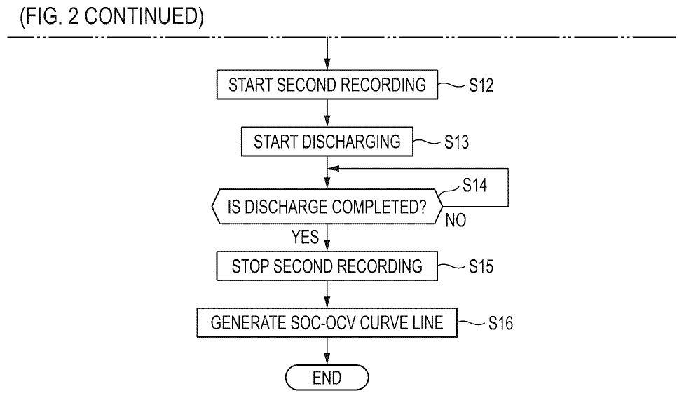

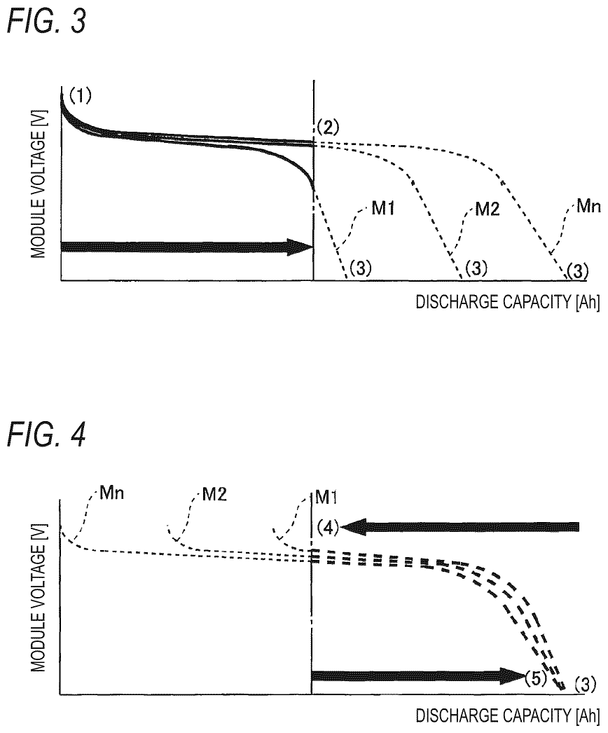

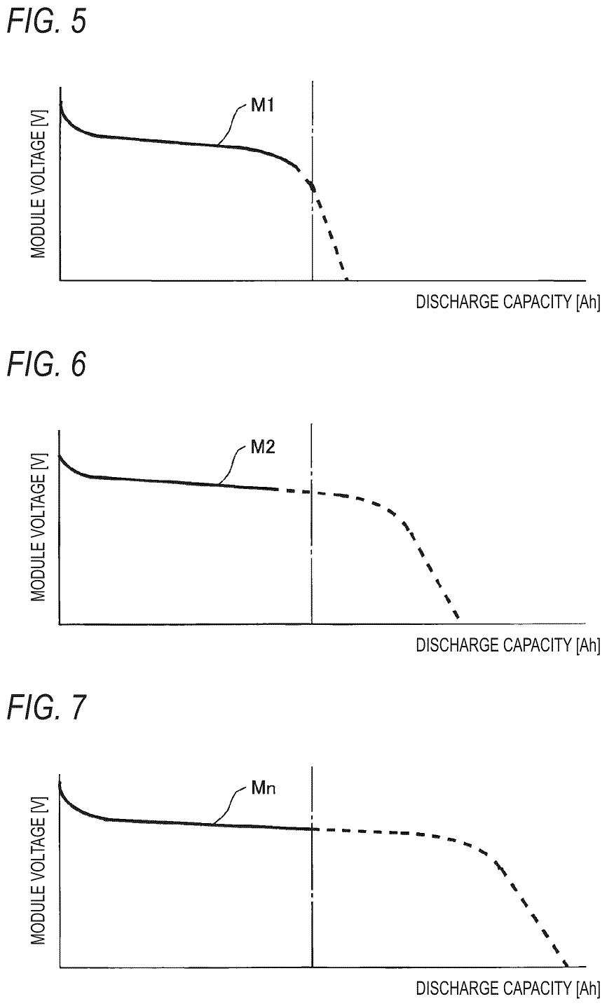

FIG. 2 is a flowchart illustrating a process of the system controller 101 illustrated in FIG. 1 acquiring the discharge capacity-module voltage curve line (SOC-OCV curve line) indicating a correlation between the discharge capacity and the voltage of the storage battery modules M1 to Mn. FIGS. 3 and 4 are graphs illustrating a correlation between the discharge capacity and the voltage of the storage battery modules M1 to Mn during the execution of the process illustrated in the flowchart of FIG. 2. Further, FIGS. 5 and 7 are graphs illustrating the discharge capacity-module voltage curve line generated by the process illustrated in the flowchart of FIG. 2.

First, in step S1 illustrated in FIG. 2, the system controller 101 determines the target storage battery strings STR1 to STRm that need to update the basic data used for the state estimation such as the SOH or the SOC. Next, in step S2, the system controller 101 controls the corresponding power converters PC1 to PCm to input power to the target storage battery strings STR1 to STRm. At this time, the system controller 101 brings all the storage battery modules M1 to Mn of the target storage battery strings STR1 to STRm into a fully charged state. In addition, every time the voltage of each of the storage battery modules M1 to Mn rises to a predetermined end-of-charge voltage, the string controller 102 switches the storage battery modules M1 to Mn from the connection state to the bypass state by the bypass circuits B1 to Bn corresponding to the storage battery modules M1 to Mn. The state in which the voltage of each of the storage battery modules M1 to Mn is the predetermined end-of-charge voltage is a state illustrated in (1) in FIG. 3, that is, the fully charged state of each of the storage battery modules M1 to Mn.

Here, as illustrated in FIG. 3, there is a difference in discharge capacities of the storage battery modules M1 to Mn. In the storage battery modules M1 to Mn, the higher a deterioration degree, the smaller the discharge capacity becomes, and the shorter a time from the fully charged state to a fully discharged state becomes.

Next, in step S3, the system controller 101 transmits, to the string controller 102, an instruction to switch all the storage battery modules M1 to Mn of the target storage battery strings STR1 to STRm from the bypass state to the connection state. Accordingly, all the storage battery modules M1 to Mn of the target storage battery strings STR1 to STRm are connected in series.

Next, in step S4, the system controller 101 starts recording the voltages of the storage battery modules M1 to Mn detected by the voltage sensors 12 of the target storage battery strings STR1 to STRm and currents detected by the current sensor 13. Here, the recording of a voltage and a current from step S5 to step S7 is referred to as a first recording. On the other hand, the recording of a voltage and a current from step S12 to step S15 is referred to as a second recording.

Next, in step S5, the system controller 101 controls the corresponding power converters PC1 to PCm to start discharging the target storage battery strings STR1 to STRm at a constant current and a low current.

Next, in step S6, the system controller 101 determines whether the discharge amounts of all the storage battery modules M1 to Mn of the target storage battery strings STR1 to STRm reach a predetermined discharge amount based on an integrated value of the discharge current detected by the current sensor 13. A state illustrated in (2) in FIG. 3 is a state in which the discharge amounts of all the storage battery modules M1 to Mn reach the predetermined discharge amount. If the determination is yes in step S6, the processing proceeds to step S7, and if the determination is no in step S6, step S6 is repeated.

Here, the “predetermined discharge amount” is set so that an overlapping range is generated between a discharge capacity-module voltage curve line obtained in the first recording and a discharge capacity-module voltage curve line obtained in the second recording. The storage battery modules M1 to Mn that reach an end-of-discharge voltage during the discharge of the “predetermined discharge amount” are switched from the connection state to the bypass state by the bypass circuits B1 to Bn. In this case, the discharge capacity-module voltage curve line obtained in the first recording and the discharge capacity-module voltage curve line obtained in the second recording may be discontinuous. Therefore, it is preferred to set the “predetermined discharge amount” so that the storage battery modules M1 to Mn are not switched from the connection state to the bypass state during the discharge of the “predetermined discharge amount” (during the execution of the first recording). On the other hand, when the storage battery modules M1 to Mn are switched from the connection state to the bypass state during the discharge of the “predetermined discharge amount”, processing such as smoothing or extrapolation is performed to generate a continuous discharge capacity-module voltage curve line.

Next, in step S7, the system controller 101 stops recording (first recording) the voltages of the storage battery modules M1 to Mn detected by the voltage sensors 12 of the target storage battery strings STR1 to STRm and the currents detected by the current sensor 13.

Next, in step S8, the system controller 101 controls the corresponding power converters PC1 to PCm to output the power from all the storage battery modules M1 to Mn of the target storage battery strings STR1 to SRTm. At this time, the system controller 101 brings all the storage battery modules M1 to Mn of the target storage battery strings STR1 to STRm into the fully discharged state. In addition, every time the voltage of each of the storage battery modules M1 to Mn drops to a predetermined end-of-discharge voltage, the string controller 102 switches the storage battery modules M1 to Mn from the connection state to the bypass state by the bypass circuits B1 to Bn corresponding to the storage battery modules M1 to Mn. The state in which the voltage of each of the storage battery modules M1 to Mn is the predetermined end-of-discharge voltage is a state illustrated in (3) in FIGS. 3 and (3) in FIG. 4, that is, the fully discharged state of each of the storage battery modules M1 to Mn.

Next, in step S9, the system controller 101 transmits, to the string controller 102, an instruction to switch all the storage battery modules M1 to Mn of the target storage battery strings STR1 to STRm from the bypass state to the connection state. Accordingly, all the storage battery modules M1 to Mn of the target storage battery strings STR1 to STRm are connected in series.

Next, in step S10, the system controller 101 controls the corresponding power converters PC1 to PCm to start charging the target storage battery strings STR1 to STRm at a constant current.

Next, in step S11, the system controller 101 determines whether charge amounts of all the storage battery modules M1 to Mn of the target storage battery strings STR1 to STRm reach a predetermined charge amount based on an integrated value of the charge current detected by the current sensor 13. A state illustrated in (4) in FIG. 4 is a state in which the charge amounts of all the storage battery modules M1 to Mn reach the predetermined charge amount.

Here, the “predetermined charge amount” is set so that an overlapping range is generated between the discharge capacity-module voltage curve line obtained in the first recording and the discharge capacity-module voltage curve line obtained in the second recording. The storage battery modules M1 to Mn that reach the end-of-charge voltage during the charge of the “predetermined charge amount” are switched from the connection state to the bypass state by the bypass circuits B1 to Bn. In this case, the discharge capacity-module voltage curve line obtained in the first recording and the discharge capacity-module voltage curve line obtained in the second recording may be discontinuous. Therefore, it is preferred to set the “predetermined charge amount” so that the storage battery modules M1 to Mn are not switched from the connection state to the bypass state during the charge of the “predetermined charge amount”. On the other hand, when the storage battery modules M1 to Mn are switched from the connection state to the bypass state during the charge of the “predetermined charge amount”, the processing such as smoothing or extrapolation is performed to generate the continuous discharge capacity-module voltage curve line.

If the determination is yes in step S11, the processing proceeds to step S12, and if the determination is no in step S11, step S11 is repeated. In step S12, the system controller 101 starts recording (second recording) the voltages of the storage battery modules M1 to Mn detected by the voltage sensors 12 of the target storage battery strings STR1 to STRm and the currents detected by the current sensor 13.

Next, in step S13, the system controller 101 controls the corresponding power converters PC1 to PCm to start discharging the target storage battery strings STR1 to STRm at a constant current and a low current. Here, when the storage battery modules M1 to Mn are switched from the connection state to the bypass state during the charge in step S11, the system controller 101 maintains the bypass state of the storage battery modules M1 to Mn until the middle of step S14 to be described later.

Next, in step S14, the system controller 101 determines whether the discharge of all the storage battery modules M1 to Mn of the target storage battery strings STR1 to STRm is completed based on the integrated value of the discharge current detected by the current sensor 13. A state illustrated in (5) in FIG. 4 is the fully discharged state of all the storage battery modules M1 to Mn.

Here, when the storage battery modules M1 to Mn are switched from the connection state to the bypass state during the charge in step S11, the system controller 101 maintains the storage battery modules M1 to Mn in the bypass state until the remaining discharge capacities of the storage battery modules M1 to Mn and the other storage battery modules M1 to Mn are equal to each other.

If the determination is yes in step S14, the processing proceeds to step S15, and if the determination is no in step S14, step S14 is repeated. In step S15, the system controller 101 stops recording (second recording) the voltages of the storage battery modules M1 to Mn detected by the voltage sensors 12 of the target storage battery strings STR1 to STRm and the currents detected by the current sensor 13.

Next, in step S16, the system controller 101 generates a discharge capacity-module voltage curve line of each of the storage battery modules M1 to Mn based on the first recording and the second recording for each of the storage battery modules M1 to Mn. Specifically, the system controller 101 generates a discharge capacity-module voltage curve line in a high SOC region based on the first recording for each of the storage battery modules M1 to Mn. On the other hand, the system controller 101 generates a discharge capacity-module voltage curve line in a low SOC region based on the second recording of each of the storage battery modules M1 to Mn. The system controller 101 synthesizes the discharge capacity-module voltage curve line in the high SOC region and the discharge capacity-module voltage curve line in the low SOC region to generate a discharge capacity-module voltage curve line indicating a transition of the voltage from the fully charged state to the fully discharged state.

Here, as described above, it is also conceivable that the storage battery modules M1 to Mn are switched from the connection state to the bypass state during the execution of the first recording or the second recording. In this case, the system controller 101 executes the processing such as smoothing or extrapolation on a boundary between a range corresponding to the first recording and a range corresponding to the second recording in the discharge capacity-module voltage curve lines, and generates a continuous discharge capacity-module voltage curve line as illustrated in FIGS. 5 to 7. Thus, the processing illustrated in the flowchart in FIG. 3 is ended.

As described above, the storage battery control device 100 of the present embodiment executes the following first to fifth processes.

### (First Process)

The plurality of storage battery modules M1 to Mn are discharged by the predetermined discharge amount from the fully charged state (predetermined charged state), and the module voltage and the string current are recorded. (Second Process)

The plurality of storage battery modules M1 to Mn that are discharged by the predetermined discharge amount are discharged to the fully discharged state (predetermined discharged state). (Third Process)

The plurality of storage battery modules M1 to Mn that are discharged to the fully discharged state (predetermined discharged state) are charged by the predetermined charge amount. (Fourth Process)

The plurality of storage battery modules M1 to Mn that are charged by the predetermined charge amount are discharged to the fully discharged state (predetermined discharged state), and the voltages of the storage battery modules M1 to Mn and the currents of the storage battery strings STR1 to STRm are recorded. (Fifth Process)

Based on the module voltage and the string current recorded in the first process and the module voltage and the string current recorded in the fourth process, voltage transition information indicating voltage transitions at the time of discharging the plurality of storage battery modules M1 to Mn is generated.

Accordingly, it is possible to prevent the storage battery modules M1 to Mn from being switched from the connection state to the bypass state in the middle of a discharge mode executed to acquire the voltage transition information indicating the voltage transitions at the time of discharging the plurality of storage battery modules M1 to Mn. Therefore, even when the discharge mode is executed for each of the storage battery strings STR1 to STRm, it is possible to prevent the generation of a discontinuous range in the voltage transition information from the fully charged state (predetermined charged state) to the fully discharged state (predetermined discharged state). As described above, the voltage transition information at the time of discharging the plurality of storage battery modules M1 to Mn can be efficiently acquired, and an interruption time of the operation of the power storage system 1 can be shortened.

The predetermined discharge amount and the predetermined charge amount are set such that a part of the range (high SOC region) corresponding to the module voltage and the string current recorded in the first process in the voltage transition information at the time of discharge and a part of the range (low SOC region) corresponding to the module voltage and the string current recorded in the fourth process in the voltage transition information at the time of discharge overlap each other.

Accordingly, when the storage battery modules M1 to Mn are switched from the connection state to the bypass state in a discharge capacity corresponding to an overlapping range of the high SOC region and the low SOC region during the execution of the first process, recording information on the fourth process can be used in the overlapping range. On the other hand, when the storage battery modules M1 to Mn are switched from the connection state to the bypass state in a discharge capacity corresponding to an overlapping region of the high SOC region and the low SOC region during the execution of the third process, recording information on the first process can be used in the overlapping range. Therefore, a continuous discharge capacity-module voltage curve line can be acquired as the voltage transition information at the time of discharging the plurality of storage battery modules M1 to Mn.

In addition, when the storage battery modules M1 to Mn are switched from the connection state to the bypass state during the execution of the third process, the storage battery control device 100 maintains the bypass state of the storage battery modules M1 to Mn until the discharge capacities of the storage battery modules M1 to Mn in the bypass state and the other storage battery modules M1 to Mn in the connection state are equal to each other in the fourth process. Accordingly, in the fourth process, the plurality of storage battery modules M1 to Mn can be simultaneously discharged to the fully discharged state (predetermined discharged state).

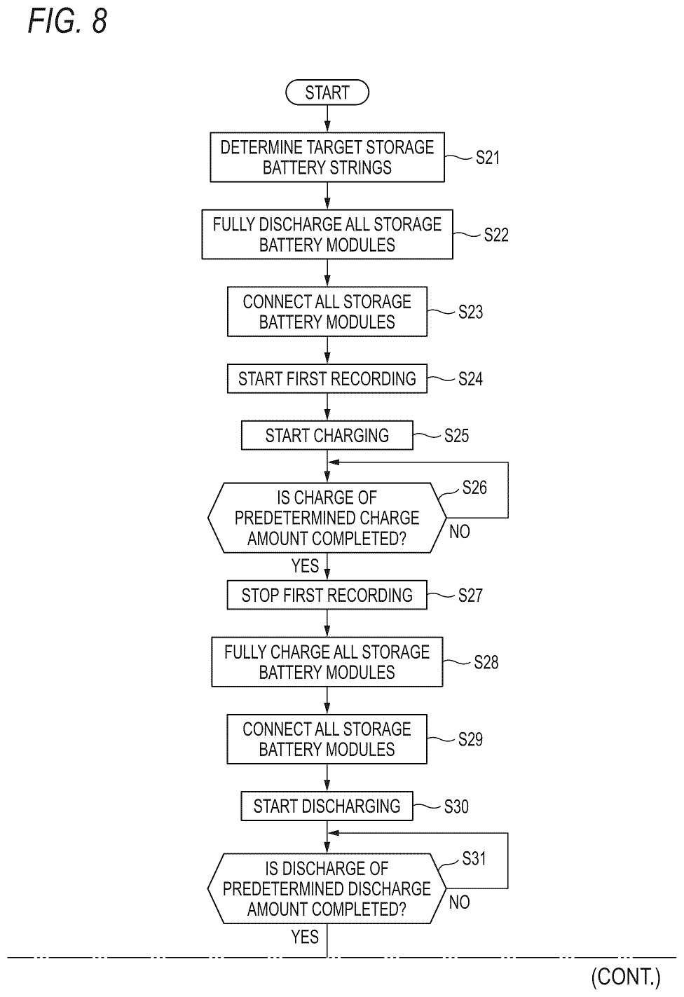

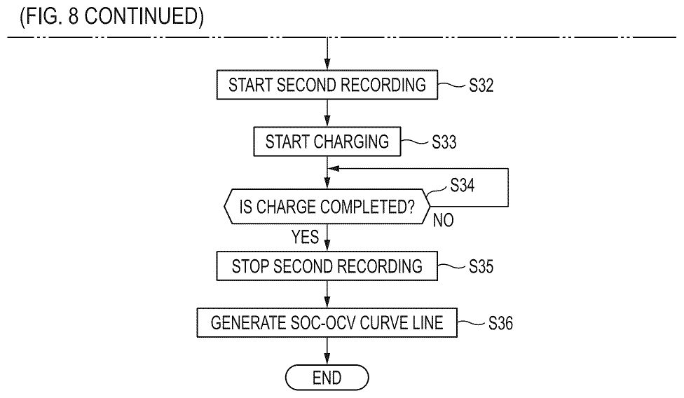

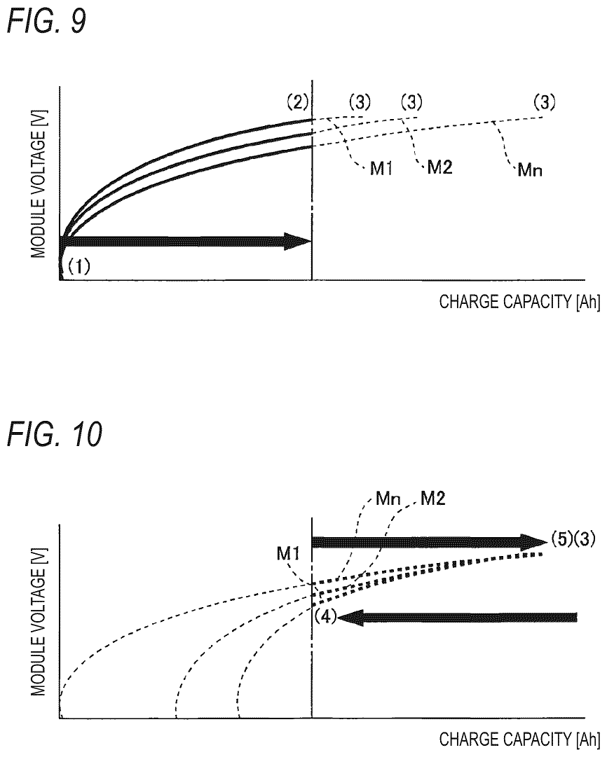

FIG. 8 is a flowchart illustrating a process of the system controller 101 illustrated in FIG. 1 acquiring the charge capacity-module voltage curve line (SOC-OCV curve line) indicating a correlation between the charge capacity and the voltage of the storage battery modules M1 to Mn. FIGS. 9 and 10 are graphs illustrating a correlation between the charge capacity and the voltage of the storage battery modules M1 to Mn during the execution of the process illustrated in the flowchart of FIG. 8. Further, FIGS. 11 and 13 are graphs illustrating the charge capacity-module voltage curve line generated by the process illustrated in the flowchart of FIG. 8.

First, in step S21, the system controller 101 determines the target storage battery strings STR1 to STRm that need to update the basic data used for the state estimation such as the SOH or the SOC. Next, in step S22, the system controller 101 controls the corresponding power converters PC1 to PCm to output power from the target storage battery strings STR1 to STRm. At this time, the system controller 101 brings all the storage battery modules M1 to Mn of the target storage battery strings STR1 to STRm into the fully discharged state. In addition, every time the voltage of each of the storage battery modules M1 to Mn rises to the predetermined end-of-discharge voltage, the string controller 102 switches the storage battery modules M1 to Mn from the connection state to the bypass state by the bypass circuits B1 to Bn corresponding to the storage battery modules M1 to Mn. The state in which the voltage of each of the storage battery modules M1 to Mn is the predetermined end-of-discharge voltage is a state illustrated in (1) in FIG. 9, that is, the fully discharged state of each of the storage battery modules M1 to Mn.

Here, as illustrated in FIG. 9, there is a difference in charge capacities of the storage battery modules M1 to Mn. In the storage battery modules M1 to Mn, the higher the deterioration degree, the smaller the charge capacity becomes, and the shorter the time from the fully discharged state to the fully charged state becomes.

Next, in step S23, the system controller 101 transmits, to the string controller 102, an instruction to switch all the storage battery modules M1 to Mn of the target storage battery strings STR1 to STRm from the bypass state to the connection state. Accordingly, all the storage battery modules M1 to Mn of the target storage battery strings STR1 to STRm are connected in series.

Next, in step S24, the system controller 101 starts recording the voltages of the storage battery modules M1 to Mn detected by the voltage sensors 12 of the target storage battery strings STR1 to STRm and the currents detected by the current sensor 13. Here, the recording of a voltage and a current from step S25 to step S27 is referred to as a first recording. On the other hand, the recording of a voltage and a current from step S32 to step S35 is referred to as a second recording.

Next, in step S25, the system controller 101 controls the corresponding power converters PC1 to PCm to start charging the target storage battery strings STR1 to STRm at a constant current and a low current.

Next, in step S26, the system controller 101 determines whether the charge amounts of all the storage battery modules M1 to Mn of the target storage battery strings STR1 to STRm reach the predetermined charge amount based on the integrated value of the charge current detected by the current sensor 13. A state illustrated in (2) in FIG. 9 is a state in which the charge amounts of all the storage battery modules M1 to Mn reach the predetermined charge amount. If the determination is yes in step S26, the processing proceeds to step S27, and if the determination is no in step S26, step S26 is repeated.

Here, the “predetermined charge amount” is set so that an overlapping range is generated between the charge capacity-module voltage curve line obtained in the first recording and the discharge capacity-module voltage curve line obtained in the second recording. The storage battery modules M1 to Mn that reach the end-of-charge voltage during the charge of the “predetermined charge amount” are switched from the connection state to the bypass state by the bypass circuits B1 to Bn. In this case, the charge capacity-module voltage curve line obtained in the first recording and the charge capacity-module voltage curve line obtained in the second recording may be discontinuous. Therefore, it is preferred to set the “predetermined charge amount” so that the storage battery modules M1 to Mn are not switched from the connection state to the bypass state during the charge of the “predetermined charge amount” (during the execution of the first recording). On the other hand, when the storage battery modules M1 to Mn are switched from the connection state to the bypass state during the charge of the “predetermined charge amount”, the processing such as smoothing or extrapolation is performed to generate the continuous discharge capacity-module voltage curve line.

Next, in step S27, the system controller 101 stops recording (first recording) the voltages of the storage battery modules M1 to Mn detected by the voltage sensors 12 of the target storage battery strings STR1 to STRm and the currents detected by the current sensor 13.

Next, in step S28, the system controller 101 controls the corresponding power converters PC1 to PCm to input power to all the storage battery modules M1 to Mn of the target storage battery strings STR1 to SRTm. At this time, the system controller 101 brings all the storage battery modules M1 to Mn of the target storage battery strings STR1 to STRm into the fully charged state. In addition, every time the voltage of each of the storage battery modules M1 to Mn rises to the predetermined end-of-charge voltage, the string controller 102 switches the storage battery modules M1 to Mn from the connection state to the bypass state by the bypass circuits B1 to Bn corresponding to the storage battery modules M1 to Mn. The state in which the voltage of each of the storage battery modules M1 to Mn is the predetermined end-of-charge voltage is a state illustrated in (3) in FIGS. 9 and (3) in FIG. 10, that is, the fully charged state of each of the storage battery modules M1 to Mn.

Next, in step S29, the system controller 101 transmits, to the string controller 102, an instruction to switch all the storage battery modules M1 to Mn of the target storage battery strings STR1 to STRm from the bypass state to the connection state. Accordingly, all the storage battery modules M1 to Mn of the target storage battery strings STR1 to STRm are connected in series.

Next, in step S30, the system controller 101 controls the corresponding power converters PC1 to PCm to start discharging the target storage battery strings STR1 to STRm at a constant current.

Next, in step S31, the system controller 101 determines whether the discharge amounts of all the storage battery modules M1 to Mn of the target storage battery strings STR1 to STRm reach the predetermined discharge amount based on the integrated value of the discharge current detected by the current sensor 13. A state illustrated in (4) in FIG. 10 is a state in which the discharge amounts of all the storage battery modules M1 to Mn reach the predetermined discharge amount.

Here, the “predetermined discharge amount” is set so that an overlapping range is generated between the charge capacity-module voltage curve line obtained in the first recording and the charge capacity-module voltage curve line obtained in the second recording. The storage battery modules M1 to Mn that reach an end-of-discharge voltage during the discharge of the “predetermined discharge amount” are switched from the connection state to the bypass state by the bypass circuits B1 to Bn. In this case, the charge capacity-module voltage curve line obtained in the first recording and the charge capacity-module voltage curve line obtained in the second recording may be discontinuous. Therefore, it is preferred to set the “predetermined discharge amount” so that the storage battery modules M1 to Mn are not switched from the connection state to the bypass state during the discharge of the “predetermined discharge amount”. On the other hand, when the storage battery modules M1 to Mn are switched from the connection state to the bypass state during the discharge of the “predetermined discharge amount”, the processing such as smoothing or extrapolation is performed to generate a continuous charge capacity-module voltage curve line.

If the determination is yes in step S31, the processing proceeds to step S32, and if the determination is no in step S31, step S31 is repeated. In step S32, the system controller 101 starts recording (second recording) the voltages of the storage battery modules M1 to Mn detected by the voltage sensors 12 of the target storage battery strings STR1 to STRm and the currents detected by the current sensor 13.

Next, in step S33, the system controller 101 controls the corresponding power converters PC1 to PCm to start charging the target storage battery strings STR1 to STRm at a constant current and a low current. Here, when the storage battery modules M1 to Mn are switched from the connection state to the bypass state during the discharge in step S31, the system controller 101 maintains the bypass state of the storage battery modules M1 to Mn until the middle of step S34 to be described later.

Next, in step S34, the system controller 101 determines whether the charge of all the storage battery modules M1 to Mn of the target storage battery strings STR1 to STRm is completed based on the integrated value of the charge current detected by the current sensor 13. A state illustrated in (5) in FIG. 10 is the fully charged state of all the storage battery modules M1 to Mn.

Here, when the storage battery modules M1 to Mn are switched from the connection state to the bypass state during the discharge in step S31, the system controller 101 maintains the storage battery modules M1 to Mn in the bypass state until the remaining charge capacities of the storage battery modules M1 to Mn and the other storage battery modules M1 to Mn are equal to each other.

If the determination is yes in step S34, the processing proceeds to step S35, and if the determination is no in step S34, step S34 is repeated. In step S35, the system controller 101 stops recording (second recording) the voltages of the storage battery modules M1 to Mn detected by the voltage sensors 12 of the target storage battery strings STR1 to STRm and the currents detected by the current sensor 13.

Next, in step S36, the system controller 101 generates a charge capacity-module voltage curve line of each of the storage battery modules M1 to Mn based on the first recording and the second recording for each of the storage battery modules M1 to Mn. Specifically, the system controller 101 generates a charge capacity-module voltage curve line in the low SOC region based on the first recording for each of the storage battery modules M1 to Mn. On the other hand, the system controller 101 generates a charge capacity-module voltage curve line in the high SOC region based on the second recording of each of the storage battery modules M1 to Mn. The system controller 101 synthesizes the charge capacity-module voltage curve line in the low SOC region and the charge capacity-module voltage curve line in the high SOC region to generate a charge capacity-module voltage curve line indicating a transition of the voltage from the fully discharged state to the fully charged state.

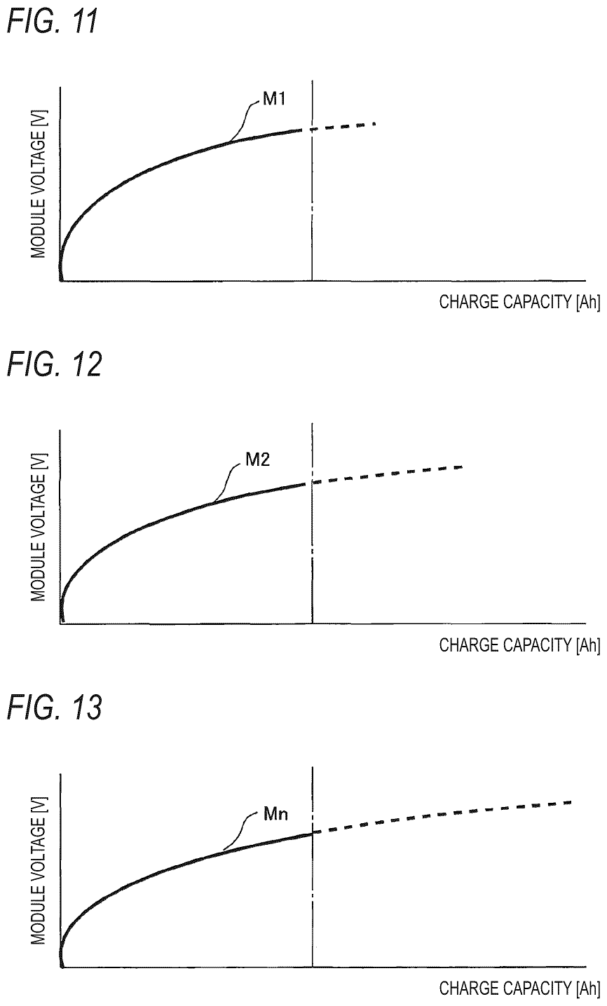

Here, as described above, it is also conceivable that the storage battery modules M1 to Mn are switched from the connection state to the bypass state during the execution of the first recording or the second recording. In this case, the system controller 101 executes the processing such as smoothing or extrapolation on a boundary between a range corresponding to the first recording and a range corresponding to the second recording in the charge capacity-module voltage curve lines, and generates a continuous charge capacity-module voltage curve line as illustrated in FIGS. 11 to 13. Thus, the processing illustrated in the flowchart in FIG. 8 is ended.

As described above, the storage battery control device 100 of the present embodiment executes the following first to fifth processes.

### (First Process)

The plurality of storage battery modules M1 to Mn are charged by the predetermined charge amount from the fully discharged state (predetermined discharged state), and the module voltage and the string current are recorded. (Second Process)

The plurality of storage battery modules M1 to Mn that are charged by the predetermined charge amount are charged to the fully charged state (predetermined charged state). (Third Process)

The plurality of storage battery modules M1 to Mn that are charged to the fully charged state (predetermined charged state) are discharged by the predetermined discharge amount. (Fourth Process)

The plurality of storage battery modules M1 to Mn that are discharged by the predetermined discharge amount are charged to the fully charged state (predetermined charged state), and the module voltage and the string current are recorded. (Fifth Process)

Based on the module voltage and the string current recorded in the first process and the module voltage and the string current recorded in the fourth process, voltage transition information indicating voltage transitions at the time of charging the plurality of storage battery modules M1 to Mn is generated.

Accordingly, it is possible to prevent the storage battery modules M1 to Mn from being switched from the connection state to the bypass state in the middle of a charge mode executed to acquire the voltage transition information indicating the voltage transitions at the time of charging the plurality of storage battery modules M1 to Mn. Therefore, even when the charge mode is executed for each of the storage battery strings STR1 to STRm, it is possible to prevent the generation of a discontinuous range in the voltage transition information from the fully discharged state (predetermined discharged state) to the fully charged state (predetermined charged state). As described above, the voltage transition information at the time of charging the plurality of storage battery modules M1 to Mn can be efficiently acquired, and an interruption time of the operation of the power storage system 1 can be shortened.

The predetermined charge amount and the predetermined discharge amount are set such that a part of the range (low SOC region) corresponding to the module voltage and the string current recorded in the first process in the voltage transition information at the time of charge and a part of the range (high SOC region) corresponding to the module voltage and the string current recorded in the fourth process in the voltage transition information at the time of charge overlap each other.

Accordingly, when the storage battery modules M1 to Mn are switched from the connection state to the bypass state in a charge capacity corresponding to an overlapping range of the low SOC region and the high SOC region during the execution of the first process, the recording information on the fourth process can be used in the overlapping range. On the other hand, when the storage battery modules M1 to Mn are switched from the connection state to the bypass state in a charge capacity corresponding to an overlapping range of the low SOC region and the high SOC region during the execution of the third process, the recording information on the first process can be used in the overlapping range. Therefore, a continuous charge capacity-module voltage curve line can be acquired as the voltage transition information at the time of charging the plurality of storage battery modules M1 to Mn.

In addition, when the storage battery modules M1 to Mn are switched from the connection state to the bypass state during the execution of the third process, the storage battery control device 100 maintains the bypass state of the storage battery modules M1 to Mn until the charge capacities of the storage battery modules M1 to Mn in the bypass state and the other storage battery modules M1 to Mn in the connection state are equal to each other in the fourth process. Accordingly, in the fourth process, the plurality of storage battery modules M1 to Mn can be simultaneously charged to the fully charged state (predetermined charged state).

Although the present invention has been described above based on the above embodiments, the present invention is not limited to the above embodiments, and modifications may be made without departing from the gist of the present invention, and publicly known or well-known techniques may be appropriately combined.

For example, in the above embodiments, the “predetermined charged state” described in the claims is defined as the “fully charged state”. However, the “predetermined charged state” is not limited to the “fully charged state”, and includes a “state in which the remaining charge capacity is small and close to being fully charged”, a “state in which the remaining charge capacity exceeds a small range and is far from being fully charged”, and the like. In addition, the above embodiments, the “predetermined discharged state” described in the claims is defined as the “fully discharged state”. However, the “predetermined discharged state” is not limited to the “fully discharged state”, and includes a “state in which the remaining discharge capacity is small and close to being fully discharged”, a “state in which the remaining discharge capacity exceeds a small range and is far from being fully discharged”, and the like.

Here, features of embodiments of the storage battery control device and the power storage system according to the present invention described above will be briefly summarized and listed in the following [1] to [8].

[1] A storage battery control device (100) for controlling a power storage system (1) including a storage battery string (STR1 to STRm) including a plurality of storage batteries (M1 to Mn) connected in series and a plurality of bypass circuits (B1 to Bn) provided for the respective storage batteries and configured to switch the storage batteries between a connection state and a bypass state, and a power converter (PC1 to PCm) configured to convert input and output power of the storage battery string, the storage battery control device (100) executing:
a first process of discharging the plurality of storage batteries from a predetermined charged state by a predetermined discharge amount and recording a voltage of the storage batteries and a current of the storage battery string;
a second process of discharging the plurality of storage batteries that are discharged by the predetermined discharge amount to a predetermined discharged state;
a third process of charging the plurality of storage batteries that are discharged to the predetermined discharged state by a predetermined charge amount;
a fourth process of discharging the plurality of storage batteries that are charged by the predetermined charge amount to the predetermined discharged state and recording a voltage of the storage batteries and a current of the storage battery string; and
a fifth process of generating voltage transition information indicating voltage transitions at the time of discharging the plurality of storage batteries based on the voltage of the storage batteries and the current of the storage battery string recorded in the first process and the voltage of the storage batteries and the current of the storage battery string recorded in the fourth process.

[2] The storage battery control device according to [1], in which the predetermined discharge amount and the predetermined charge amount are set such that a part of a range corresponding to the voltage of the storage batteries and the current of the storage battery string recorded in the first process in the voltage transition information and a part of a range corresponding to the voltage of the storage batteries and the current of the storage battery string recorded in the fourth process in the voltage transition information overlap each other.

[3] The storage battery control device according to [1] or [2], in which when the storage batteries are switched from the connection state to the bypass state by the bypass circuits during the execution of the third process, the bypass state of the storage batteries is maintained until discharge capacities of the storage batteries in the bypass state and the storage batteries in the connection state are equal to each other in the fourth process.

[4] A storage battery control device for controlling a power storage system including a storage battery string including a plurality of storage batteries connected in series and a plurality of bypass circuits provided for the respective storage batteries and configured to switch the storage batteries between a connection state and a bypass state, and a power converter configured to convert input and output power of the storage battery string, the storage battery control device executing:
a first process of charging the plurality of storage batteries from a predetermined discharged state by a predetermined charge amount and recording a voltage of the storage batteries and a current of the storage battery string;
a second process of charging the plurality of storage batteries that are charged by the predetermined charge amount to a predetermined charged state;
a third process of discharging the plurality of storage batteries that are charged to the predetermined charged state by a predetermined discharge amount;
a fourth process of charging the plurality of storage batteries that are discharged by the predetermined discharge amount to the predetermined charged state and recording a voltage of the storage batteries and a current of the storage battery string; and
a fifth process of generating voltage transition information indicating voltage transitions at the time of charging the plurality of storage batteries based on the voltage of the storage batteries and the current of the storage battery string recorded in the first process and the voltage of the storage batteries and the current of the storage battery string recorded in the fourth process.

[5] The storage battery control device according to [4], in which the predetermined charge amount and the predetermined discharge amount are set such that a part of a range corresponding to the voltage of the storage batteries and the current of the storage battery string recorded in the first process in the voltage transition information and a part of a range corresponding to the voltage of the storage batteries and the current of the storage battery string recorded in the fourth process in the voltage transition information overlap each other.

[6] The storage battery control device according to [4] or [5], in which when the storage batteries are switched from the connection state to the bypass state by the bypass circuits during the execution of the third process, the bypass state of the storage batteries is maintained until charge capacities of the storage batteries in the bypass state and the storage batteries in the connection state are equal to each other in the fourth process.

[7] A power storage system including:
a storage battery string including a plurality of storage batteries connected in series and a plurality of bypass circuits provided for the respective storage batteries and configured to switch the storage batteries between a connection state and a bypass state;
a power converter configured to convert input and output power of the storage battery string; and
a storage battery control device configured to control the bypass circuits and the power converter, in which
the storage battery control device executes:
   a first process of discharging the plurality of storage batteries from a predetermined charged state by a predetermined discharge amount and recording a voltage of the storage batteries and a current of the storage battery string;
   a second process of discharging the plurality of storage batteries that are discharged by the predetermined discharge amount to a predetermined discharged state;
   a third process of charging the plurality of storage batteries that are discharged to the predetermined discharged state by a predetermined charge amount;
   a fourth process of discharging the plurality of storage batteries that are charged by the predetermined charge amount to the predetermined discharged state and recording a voltage of the storage batteries and a current of the storage battery string; and
   a fifth process of generating voltage transition information indicating voltage transitions at the time of discharging the plurality of storage batteries based on the voltage of the storage batteries and the current of the storage battery string recorded in the first process and the voltage of the storage batteries and the current of the storage battery string recorded in the fourth process.

[8] A power storage system including:
a storage battery string including a plurality of storage batteries connected in series and a plurality of bypass circuits provided for the respective storage batteries and configured to switch the storage batteries between a connection state and a bypass state;
a power converter configured to convert input and output power of the storage battery string; and
a storage battery control device configured to control the bypass circuits and the power converter, in which
the storage battery control device executes:
   a first process of charging the plurality of storage batteries from a predetermined discharged state by a predetermined charge amount and recording a voltage of the storage batteries and a current of the storage battery string;
   a second process of charging the plurality of storage batteries that are charged by the predetermined charge amount to a predetermined charged state;
   a third process of discharging the plurality of storage batteries that are charged to the predetermined charged state by a predetermined discharge amount;
   a fourth process of charging the plurality of storage batteries that are discharged by the predetermined discharge amount to the predetermined charged state and recording a voltage of the storage batteries and a current of the storage battery string; and
   a fifth process of generating voltage transition information indicating voltage transitions at the time of charging the plurality of storage batteries based on the voltage of the storage batteries and the current of the storage battery string recorded in the first process and the voltage of the storage batteries and the current of the storage battery string recorded in the fourth process.

The present application is based on a Japanese patent application (Japanese Patent Application No. 2022-191255) filed on Nov. 30, 2022, and the contents thereof are incorporated herein by reference.

### INDUSTRIAL APPLICABILITY

According to the present invention, an object of the present invention is to provide a power storage system and a storage battery control device capable of efficiently acquiring voltage transition information on storage batteries in the power storage system including a storage battery string in which the storage batteries are switched between a bypass state and a connection state. The present invention having this effect is useful for the storage battery control device and the power storage system.

### REFERENCE SIGNS LIST

1: power storage system
100: storage battery control device
B1 to Bn: bypass circuit
M1 to Mn: storage battery module (storage battery)
PC1 to PCm: power converter
STR1 to STRm: storage battery string

1. A storage battery control device for controlling a power storage system including a storage battery string including a plurality of storage batteries connected in series and a plurality of bypass circuits provided for the respective storage batteries and configured to switch the storage batteries between a connection state and a bypass state, and a power converter configured to convert input and output power of the storage battery string, the storage battery control device executing:
a first process of discharging the plurality of storage batteries from a predetermined charged state by a predetermined discharge amount and recording a voltage of the storage batteries and a current of the storage battery string;
a second process of discharging the plurality of storage batteries that are discharged by the predetermined discharge amount to a predetermined discharged state;
a third process of charging the plurality of storage batteries that are discharged to the predetermined discharged state by a predetermined charge amount;
a fourth process of discharging the plurality of storage batteries that are charged by the predetermined charge amount to the predetermined discharged state and recording a voltage of the storage batteries and a current of the storage battery string; and
a fifth process of generating voltage transition information indicating voltage transitions at the time of discharging the plurality of storage batteries based on the voltage of the storage batteries and the current of the storage battery string recorded in the first process and the voltage of the storage batteries and the current of the storage battery string recorded in the fourth process.

2. The storage battery control device according to claim 1, wherein
the predetermined discharge amount and the predetermined charge amount are set such that a part of a range corresponding to the voltage of the storage batteries and the current of the storage battery string recorded in the first process in the voltage transition information and a part of a range corresponding to the voltage of the storage batteries and the current of the storage battery string recorded in the fourth process in the voltage transition information overlap each other.

3. The storage battery control device according to claim 1, wherein
when the storage batteries are switched from the connection state to the bypass state by the bypass circuits during the execution of the third process, the bypass state of the storage batteries is maintained until discharge capacities of the storage batteries in the bypass state and the storage batteries in the connection state are equal to each other in the fourth process.

4. A storage battery control device for controlling a power storage system including a storage battery string including a plurality of storage batteries connected in series and a plurality of bypass circuits provided for the respective storage batteries and configured to switch the storage batteries between a connection state and a bypass state, and a power converter configured to convert input and output power of the storage battery string, the storage battery control device executing:
a first process of charging the plurality of storage batteries from a predetermined discharged state by a predetermined charge amount and recording a voltage of the storage batteries and a current of the storage battery string;
a second process of charging the plurality of storage batteries that are charged by the predetermined charge amount to a predetermined charged state;
a third process of discharging the plurality of storage batteries that are charged to the predetermined charged state by a predetermined discharge amount;
a fourth process of charging the plurality of storage batteries that are discharged by the predetermined discharge amount to the predetermined charged state and recording a voltage of the storage batteries and a current of the storage battery string; and
a fifth process of generating voltage transition information indicating voltage transitions at the time of charging the plurality of storage batteries based on the voltage of the storage batteries and the current of the storage battery string recorded in the first process and the voltage of the storage batteries and the current of the storage battery string recorded in the fourth process.

5. The storage battery control device according to claim 4, wherein
the predetermined charge amount and the predetermined discharge amount are set such that a part of a range corresponding to the voltage of the storage batteries and the current of the storage battery string recorded in the first process in the voltage transition information and a part of a range corresponding to the voltage of the storage batteries and the current of the storage battery string recorded in the fourth process in the voltage transition information overlap each other.

6. The storage battery control device according to claim 4, wherein
when the storage batteries are switched from the connection state to the bypass state by the bypass circuits during the execution of the third process, the bypass state of the storage batteries is maintained until charge capacities of the storage batteries in the bypass state and the storage batteries in the connection state are equal to each other in the fourth process.

7. A power storage system comprising:
a storage battery string including a plurality of storage batteries connected in series and a plurality of bypass circuits provided for the respective storage batteries and configured to switch the storage batteries between a connection state and a bypass state;
a power converter configured to convert input and output power of the storage battery string; and
a storage battery control device configured to control the bypass circuits and the power converter, wherein
the storage battery control device executes:
a first process of discharging the plurality of storage batteries from a predetermined charged state by a predetermined discharge amount and recording a voltage of the storage batteries and a current of the storage battery string;
a second process of discharging the plurality of storage batteries that are discharged by the predetermined discharge amount to a predetermined discharged state;
a third process of charging the plurality of storage batteries that are discharged to the predetermined discharged state by a predetermined charge amount;
a fourth process of discharging the plurality of storage batteries that are charged by the predetermined charge amount to the predetermined discharged state and recording a voltage of the storage batteries and a current of the storage battery string; and
a fifth process of generating voltage transition information indicating voltage transitions at the time of discharging the plurality of storage batteries based on the voltage of the storage batteries and the current of the storage battery string recorded in the first process and the voltage of the storage batteries and the current of the storage battery string recorded in the fourth process.

8. A power storage system comprising:
a storage battery string including a plurality of storage batteries connected in series and a plurality of bypass circuits provided for the respective storage batteries and configured to switch the storage batteries between a connection state and a bypass state;
a power converter configured to convert input and output power of the storage battery string; and
a storage battery control device configured to control the bypass circuits and the power converter, wherein
the storage battery control device executes:
a first process of charging the plurality of storage batteries from a predetermined discharged state by a predetermined charge amount and recording a voltage of the storage batteries and a current of the storage battery string;
a second process of charging the plurality of storage batteries that are charged by the predetermined charge amount to a predetermined charged state;
a third process of discharging the plurality of storage batteries that are charged to the predetermined charged state by a predetermined discharge amount;
a fourth process of charging the plurality of storage batteries that are discharged by the predetermined discharge amount to the predetermined charged state and recording a voltage of the storage batteries and a current of the storage battery string; and
a fifth process of generating voltage transition information indicating voltage transitions at the time of charging the plurality of storage batteries based on the voltage of the storage batteries and the current of the storage battery string recorded in the first process and the voltage of the storage batteries and the current of the storage battery string recorded in the fourth process.
